(19) United States
(12) Patent Application Publication
(10) Pub. No.: US 2026/0149445 A1
(43) Pub. Date: May 28, 2026

(54) PROTECTION CIRCUIT FOR SEMICONDUCTOR DEVICES AND METHOD OF MANUFACTURE

(71) Applicant: Taiwan Semiconductor Manufacturing Company, Ltd., Hsinchu (TW)

(72) Inventors: Yi-An Lai, Taipei City (TW); Chan-Hong Chern, Palo Alto, CA (US); Stefan Rusu, Sunnyvale, CA (US)

(21) Appl. No.: 19/061,074

(22) Filed: Feb. 24, 2025

Related U.S. Application Data
(60) Provisional application No. 63/725,042, filed on Nov. 26, 2024.

(51) Int. Cl. H03K 17/081

(52) U.S. Cl. CPC H03K 17/08104

(57) ABSTRACT

A protection circuit that can be integrated with a GaN high-voltage device includes a main discharge path composed of a forward-triggering field-effect transistor (FET) and a reverse-triggering FET, connected in series between a signal input and a reference input. A first voltage-divider network comprising forward-oriented rectifiers and a second voltage-divider network comprises reverse-oriented rectifiers are connected between the signal input and the reference input. The gate of the forward-triggering FET is coupled to an intermediate node of the first voltage-divider network, allowing it to receive a voltage that is intermediate between the signal input and the reference input. At least one forward-oriented rectifier in the first voltage-divider network, protects the gate from voltage spikes originating at the reference input. Similarly, the gate of the reverse-triggering FET is coupled to an intermediate node of the second voltage-divider network, providing analogous protection and voltage control.

### REFERENCE TO RELATED APPLICATION

This Application claims priority to U.S. Provisional Application No. 63/725,042, filed on Nov. 26, 2024, the contents of which are hereby incorporated by reference in their entirety.

### BACKGROUND

In recent years, the demand for high-voltage transistors capable of operating at high breakdown voltages (e.g., greater than approximately 50V) and high frequencies has grown significantly. These types of transistors are essential in applications such as power amplifiers, low-noise amplifiers, and power inverters. They are widely used in radio frequency (RF) and microwave systems, as well as millimeter-wave technologies, supporting diverse fields including wireless communications, radar systems, medical imaging, satellite communications, and electric vehicles. There has been a long felt need for high-voltage transistors that combine high power efficiency, low noise, and fast switching speeds for use in both traditional and emerging technologies.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIGS. 1-5 provide circuit diagrams for IC devices with gate protections circuits according to some embodiments of the present disclosure.

FIG. 6 illustrates a cross-sectional view of an IC device with exemplary semiconductor devices that can form high-voltage devices and protection circuits in accordance with some embodiments.

FIG. 7 illustrates a cross-sectional view of an IC device with A voltage-divider network in accordance with some embodiments.

FIGS. 8A-9 illustrate series connected transistors providing primary discharge paths for protection circuits in accordance with some embodiments.

FIGS. 10-23 provide a series of cross-sectional views illustrating a process of forming high-voltage devices and protection circuits in accordance with some embodiments.

FIG. 24 provides a flow chart for a process of forming high-voltage devices and protection circuits in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

Silicon-based transistors have been the industry standard in semiconductors for over four decades, primarily due to silicon's low cost and favorable electrical properties. However, as semiconductor components continue to scale down in size, fabricating high-voltage transistors on silicon substrates has become increasingly difficult. This challenge arises from silicon's limitations in handling high-voltages efficiently. A promising alternative is the use of high electron mobility transistors (HEMTs), which offer advantages such as fast switching speeds, high efficiency, and low noise performance. These characteristics make HEMTs well-suited for high-frequency and high-power applications.

HEMTs are typically fabricated using type III-V semiconductors like gallium nitride (GaN), which exhibit high carrier mobility and wide bandgaps—key properties for high-voltage and high-power applications. A typical HEMT structure includes a channel layer made of a type III-V semiconductor, such as GaN, beneath a barrier layer composed of a ternary III-V compound semiconductor, such as aluminum gallium nitride (AlGaN). The barrier layer and the channel layer interact through polarization effects (spontaneous and piezoelectric polarization) to form a two-dimensional electron gas (2 DEG), confined to a narrow region at the interface (heterojunction) between the two layers. This interfacial region serves as the transistor's channel, providing high electron mobility and low resistance. To reduce production costs, the barrier and channel layers can be formed by epitaxial growth on a silicon substrate.

Challenges affecting HEMTs are that they are limited to N-channel operation and have a relatively low gate breakdown voltage. For instance, a 650V enhancement-mode GaN HEMT may exhibit a gate breakdown voltage of only about 11-12V. Consequently, it is common practice to equip GaN HEMTs and similar devices with gate protection circuits to safeguard against electrostatic discharge (ESD), power surges, and other voltage events. Existing protection circuits, however, often exhibit shortcomings such as inadequate protection across the full range of positive and negative voltage events, excessive capacitance that delays the protected device's turn-on time, or susceptibility to gate damage within the protection circuit itself.

The present disclosure provides a protection circuit design that addresses these shortcomings. The circuit includes a main discharge path composed of a forward-triggering field-effect transistor (FET) and a reverse-triggering FET, connected in series between a signal input and a reference input. Additionally, the circuit incorporates a first voltage-divider network comprising forward-oriented rectifiers and a second voltage-divider network comprising reverse-oriented rectifiers, both connected between the signal input and the reference input. The gate of the forward-triggering FET is coupled to an intermediate node of the first voltage-divider network, allowing it to receive a voltage that is intermediate between the signal input and the reference input. At least one forward-oriented rectifier in the first voltage-divider network, located between the gate of the forward-triggering FET and the reference input, protects the gate from voltage spikes originating at the reference input. Similarly, the gate of the reverse-triggering FET is coupled to an intermediate node of the second voltage-divider network, providing analogous protection and voltage control.

The first voltage-divider network regulates the gate voltage of the forward-triggering FET, ensuring that the forward-triggering FET activates (closes) when the signal input voltage exceeds the reference input voltage by a predefined first threshold. Similarly, the second voltage-divider network regulates the gate voltage of the reverse-triggering FET, causing it to activate (close) when the reference voltage exceeds the signal input voltage by a predefined second threshold. In this arrangement, the forward-and reverse-triggering FETs control the main discharge path, which activates in response to positive or negative voltage spikes occurring at either the signal input or the reference input. This configuration also protects the gates of the FETs themselves from damage during voltage spikes.

In some embodiments, the first voltage-divider network has a forward threshold voltage drop smaller than the first predefined threshold, enabling a secondary discharge path through the first voltage-divider network to activate (close) before the main discharge path. When the first voltage-divider network is active, it holds the gate of the forward triggering FET at an intermediate voltage between the signal input and the reference input. In some embodiments, that intermediate voltage is closer to the reference input than to the signal input. In some embodiments, that intermediate voltage is at the reference voltage plus no more than 25% of the difference between the signal input and reference input voltages. The second voltage-divider network can be configured similarly.

In some embodiments, the first voltage-divider network comprises a chain of rectifiers and the voltage at the gate of the forward triggering FET is determined by the node in the rectifier chain to which the gate is electrically coupled. In some embodiments, there are more rectifiers in the chain between the gate and the signal input than between the gate and the reference input. In some embodiments, there are at least three times as many rectifiers between the gate and the signal input than between the gate and the reference input. The second voltage-divider network can be configured similarly. These configurations protect the gates during voltage spikes while providing the gates with voltages to enable sufficient conduction through the main discharge path. In some embodiments, the signal input is connected to the gate of an HEMT, and the reference input is coupled to Vss.

In some embodiments, the protection circuit lacks Zenner diodes, which are difficult to form on the same substrate as an HEMT. In some embodiments, the protection circuit lacks p-type semiconductor devices, which are also difficult to form on the same substrate as an HEMT. In some embodiments, the protection circuit is integrated into the same chip as the protected device. For example, the protected device may be an HEMT, and the FETs in the protection circuit can be enhancement-mode HEMTs that utilize the same channel layer-barrier layer heterojunction. In some embodiments, the circuit elements in the voltage-divider networks such as diodes, diode-connected transistors, and resistors, also utilize the channel layer, the barrier, or the heterojunction. In some embodiments, the circuit elements are diode-connected enhancement-mode HEMTs, which increase the current carrying capacity of the secondary discharge paths.

In some embodiments, the protection circuit is fabricated using the same process steps as the protected device, eliminating additional manufacturing steps. The protected device can be an HEMT, the transistors of the protection circuit can be HEMTs, and the voltage-divider network can be composed of diode-connected HEMTs, Schottky diodes, or resistors, all utilizing the same semiconductor structure. In some embodiments, the HEMTs of the protection circuit have channel widths at least fifty times smaller than that of the protected device.

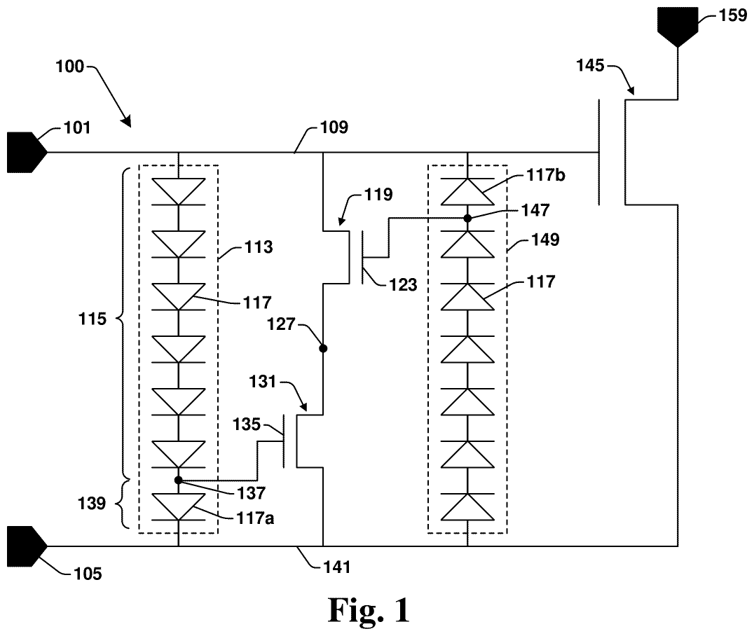

FIG. 1 provides a circuit diagram for a protection circuit 100 configured to protect the gate of a high-voltage device 145. The protection circuit 100 includes a forward-triggering FET 131, a reverse-triggering FET 119, a first voltage-divider network 113, and a second voltage-divider network 149. The forward-triggering FET 131 and the reverse-triggering FET 119 are connected in series between an input signal wire 109 and a reference signal wire 141 to provide a main discharge path. The first and second voltage-divider networks 113 and 149 are connected in series between the input signal wire 109 and the reference signal wire 141 and provide secondary discharge paths.

The first and second voltage-divider networks 113 and 149 have rectifiers 117 and can have other circuit elements. The circuit elements in the first voltage-divider network 113 are configured to apportion a voltage drop from the input signal wire 109 to the reference signal wire 141. Similarly, the circuit elements in the second voltage-divider network 149 are configured to apportion a voltage drop from the reference signal wire 141 to the input signal wire 109. The gate 135 of the forward-triggering FET 131 is coupled to a node 137 within the first voltage-divider network 113 and the gate 123 of the reverse-triggering FET 119 is coupled to a node 147 within the second voltage-divider network 149.

The rectifiers 117 in the first voltage-divider network 113 are oriented to have forward-bias directions from the input signal wire 109 to the reference signal wire 141. The combined forward threshold voltages of these rectifiers establish the overall threshold voltage for the first voltage-divider network 113. When the voltage on the input signal wire 109 (referred to as the input voltage) exceeds the voltage on the reference signal wire 141 (referred to as the reference voltage) by this threshold voltage, the first voltage-divider network 113 becomes conductive.

The voltage at the node 137, which is connected to the gate 135 of the forward-triggering FET 131, equals the reference voltage plus a fraction of the difference between the input voltage and the reference voltage. When the first voltage-divider network 113 is forward-biased, this fraction becomes a fixed voltage attenuation factor, which is determined by the ratio of the resistances in the network. Specifically, it is calculated by comparing the resistance of the first portion 115 of the first voltage-divider network 113 (between the node 137 and the input signal wire 109) with the resistance of the second portion 139 (between the node 137 and the reference signal wire 141). If the components of the first voltage-divider network 113 consist solely of rectifiers 117, the voltage attenuation factor simplifies to the number of rectifiers 117 in the first portion 115 divided by the total number of rectifiers 117 in the entire network. In the example shown in FIG. 1, this factor is 6/7.

The forward-triggering threshold voltage for the protection circuit 100 is defined as the input voltage (relative to the reference voltage) at which the gate-to-source voltage of the forward-triggering FET 131 reaches its threshold voltage, V_{T}. The source of the forward-triggering FET 131 is connected to the reference signal wire 141 and remains at the reference voltage. Therefore, the gate-to-source voltage of the forward-triggering FET 131 corresponds to the difference between the voltage at node 137 and the reference voltage. When the first voltage-divider network 113 is forward-biased, the ratio of V_{T} to the forward-triggering threshold voltage equals the voltage attenuation factor.

A positive voltage spike on the input signal wire that exceeds the forward-triggering threshold voltage will turn on the forward-triggering FET 131, connecting the floating node 127 in the main discharge path to the reference voltage. Leakage currents for type III-V semiconductor devices are typically much higher than for silicon-based semiconductor devices. Leakage currents, such as the reverse leakage current through the rectifier 117b, ensure that the gate 123 of the reverse-triggering FET 119 is well above the reference voltage when there is a positive voltage spike, causing the reverse-triggering FET 119 to also turn on. This activates the main discharge path. The currents flowing through the forward-triggering FET 131 and the reverse-triggering FET 119 are proportional to their respective gate-to-source voltage differences. The voltage at the floating node 127 adjusts dynamically so that the gate-to-source voltage of the reverse-triggering FET 119 matches that of the forward-triggering FET 131, thereby equalizing the currents through the two FETs.

During the positive voltage spike, the gate 135 of the forward-triggering FET 131 is protected by the first portion 115 of the first voltage-divider network 113, which attenuates the positive voltage spike, and the gate 123 of the reverse-triggering FET 119 is protected by the rectifier 117b, which substantially blocks the positive voltage spike. The voltage spike is discharged primarily through the main discharge path, but may also discharge through the secondary discharge path formed by the first voltage-divider network 113.

In an example, the high-voltage device 145 has a gate breakdown voltage of 12V and is normally operated by an input voltage in the range from 0V to 6V. The first and second voltage-divider networks 113 and 149 can be chains of seven rectifiers 117, each having a threshold voltage of 1.5V. The forward-triggering FET 131 and the reverse-triggering FET 119 may have threshold voltages V_{T} of 1.5V. In this configuration, both the forward-triggering threshold voltage for the protection circuit 100 and the forward threshold voltage for the first voltage-divider network 113 are 10.5V (about 80% of the gate breakdown voltage).

If a voltage spike of 12V occurs, it will become attenuated along the first voltage-divider network 113 so that the voltage at the node 137 is about 1.7V. The forward-triggering FET 131 will close and the main discharge path will also close as the voltages at the gate 123 of the reverse-triggering FET 119 and of the floating node 127 adjust to about 9.5 V and 11.2V respectively. The high-voltage device 145 will be protected from the 12V voltage spike and may similarly be protected from positive voltage spikes up to about 1000V. Negative voltage spikes on the reference signal wire 141 will be discharged by this same mechanism.

The rectifiers 117 in the second voltage-divider network 149 are oriented to have forward-bias directions from the reference signal wire 141 to the input signal wire 109. The second voltage-divider network 149 and the reverse-triggering FET 119 are configured to establish a threshold voltage for conduction from the reference signal wire 141 to the input signal wire 109 through the second voltage-divider network 149, a voltage attenuation factor that relates voltage on the reference signal wire 141 to voltage at the gate 123 of the reverse-triggering FET 119, and a reverse-triggering threshold voltage for the protection circuit 100. The configuration may be designed so that the reverse-triggering threshold voltage is the same as the forward-triggering threshold voltage except for the difference in polarity. Alternatively, the second voltage-divider network 149 may be configured to provide a reverse-triggering threshold voltage of a different magnitude from the forward-triggering threshold voltage.

During a positive voltage spike on the reference signal wire 141, or a negative voltage spike on the input signal wire 109, the gate 123 of the reverse-triggering FET 119 is protected by a portion of the second voltage-divider network 149, which attenuates the voltage spike, and the gate 135 of the forward-triggering FET 131 is protected by the rectifier 117a, which substantially blocks the voltage spike. The voltage spike is discharged primarily through the main discharge path, but may also discharge through the secondary discharge path formed by the second voltage-divider network 149.

The high-voltage device 145 may be an HEMT or other high-voltage device connected between the input signal wire 109 and the reference signal wire 141. The high-voltage source 159 can provide a voltage of 50 volts or higher. Other high-voltage devices (not shown) can be connected between the high-voltage device 145 and the high-voltage source 159 or between the high-voltage device 145 and the reference signal wire 141. The input signal wire 109 can include a metal interconnect electrically connecting an input terminal 101 to the gate of the high-voltage device 145. The input signal wire 109 can include a metal interconnect electrically connecting a source of the high-voltage device 145 to the reference terminal 105. The input terminal 101 can provide voltages of about 6V or less for activating the high-voltage device 145. The reference terminal 105 can be connected to ground or some other reference voltage (Vss).

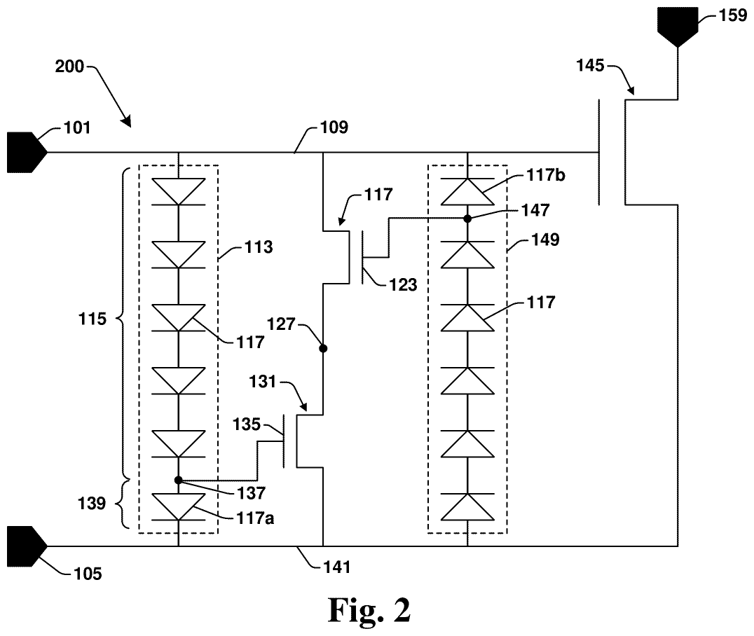

FIG. 2 provides a circuit diagram for a gate protection circuit 200, which is similar to the protection circuit 100 of FIG. 1 except that in the gate protection circuit 200, the first and second voltage-divider networks 113 and 149 each have only six rectifiers 117 so that the voltage attenuation factors are 5/6. If the threshold voltages of the rectifiers 117, the forward-triggering FET 131, and the reverse-triggering FET 119 are 1.5V, the forward-triggering and reverse-triggering threshold voltages will be 9V and −9 V respectively. If the forward-triggering FET 131 and the reverse-triggering FET 119 have threshold voltages of 1.75V, then the forward-triggering and reverse-triggering threshold voltages will be 10.5V and −10.5 V respectively.

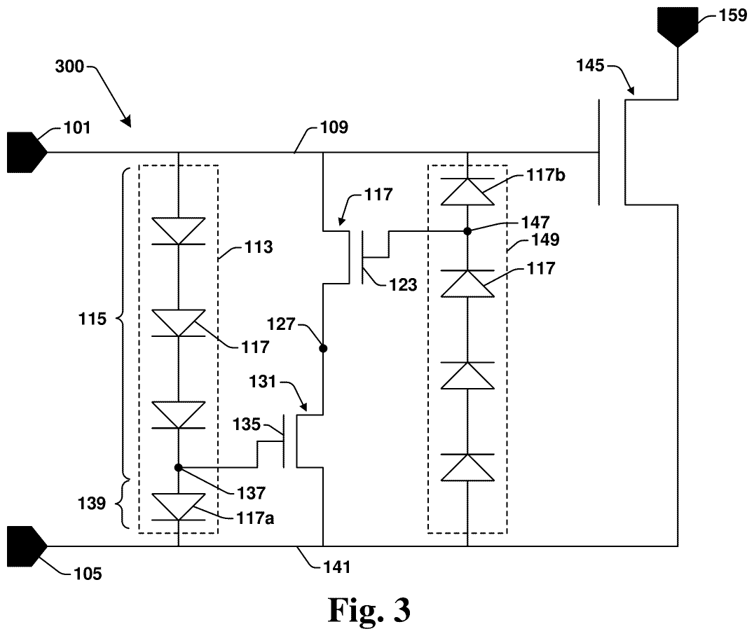

FIG. 3 provides a circuit diagram for a gate protection circuit 300, which is similar to the protection circuit 100 of FIG. 1 except that in the gate protection circuit 300, the first and second voltage-divider networks 113 and 149 each have only four rectifiers 117 so that the voltage attenuation factors are 3/4. If the threshold voltages of the rectifiers 117, the forward-triggering FET 131, and the reverse-triggering FET 119 are 1.5V, the forward-triggering and reverse-triggering threshold voltages will be 6V and −6 V respectively. A forward-triggering threshold voltage of 6V is suitable when the signal input voltage normally operates between 0V and 5V.

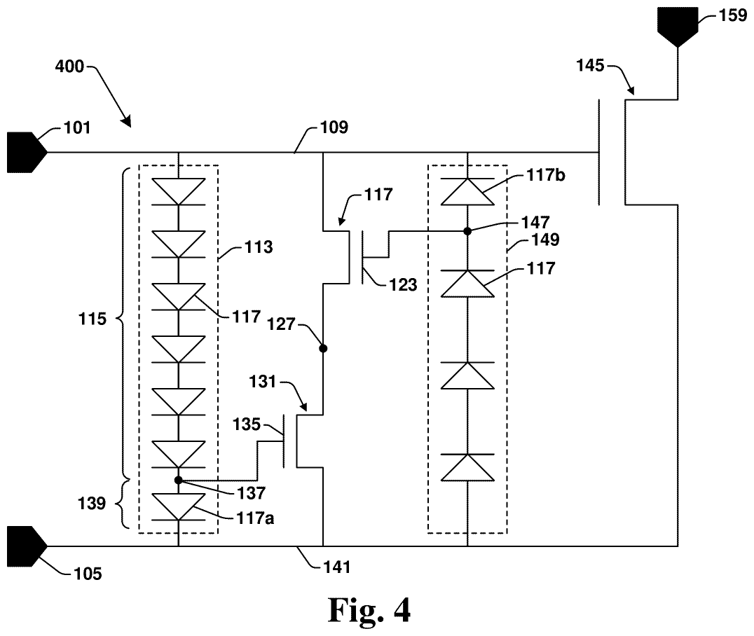

FIG. 4 provides a circuit diagram for a gate protection circuit 400, which is similar to the protection circuit 100 of FIG. 1 except that in the gate protection circuit 400, the second voltage-divider network 149 has fewer rectifiers than the first voltage-divider network 113 so that the reverse-triggering threshold volage has a lower magnitude than the forward-triggering threshold voltage. These examples illustrate how a protection circuit according to the present disclosure may be configured to achieve any suitable combination of forward and reverse-triggering threshold voltages

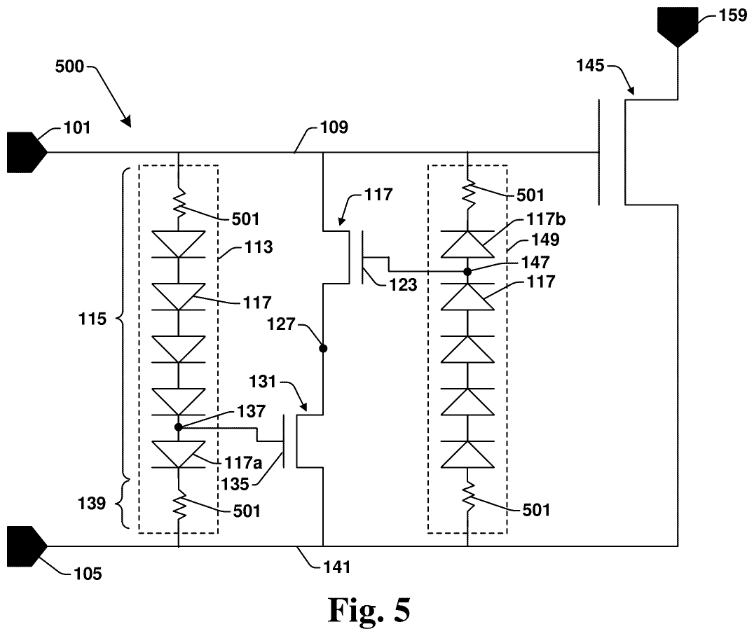

FIG. 5 provides a circuit diagram for a gate protection circuit 500, which is similar to the protection circuit 100 of FIG. 1 except that in the gate protection circuit 500, the first and second voltage-divider networks 113 and 149 include resistors 501. The resistors 501 may be used to fine tune the forward and reverse-triggering threshold voltages. Some rectifiers 117 in the first and second voltage-divider networks 113 and 149 may be replaced with resistors 501 to reduce leakage currents, but it should be noted that replacing rectifiers 117 with resistors 501 can slow the protection circuit's turn-on speed.

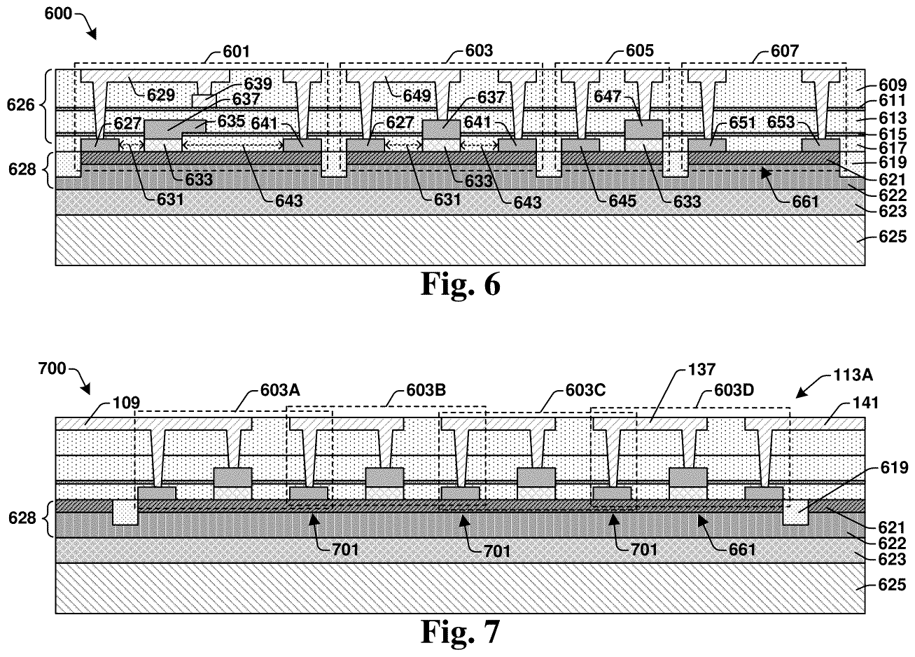

FIG. 6 illustrates a cross-sectional view of an integrated circuit device 600, showing circuit elements that can implement the high-voltage device 145 and the protection circuits 100-500. These circuit elements, which can be manufactured concurrently, include an HEMT 601, a diode-connected transistor 603, a Schottky diode 605, and a resistor 607. Each of these circuit elements includes a body region associated with the heterojunction 661. The heterojunction 661 supports a 2 DEG and is formed at the interface between an barrier layer 621 and a channel layer 622. Both the barrier layer 621 and the channel layer 622 are over a buffer layer stack 623, which in turn is disposed on a substrate 625. The buffer layer stack 623 accommodates lattice mismatch and thermal expansion coefficient differences between the substrate 625 and the channel layer 622. The buffer layer stack 623 may also provide electrical isolation.

The HEMT 601 includes a gate electrode 637 positioned over a channel region formed by the heterojunction 661 between a source electrode 627 and a drain electrode 641. The source electrode 627 and the drain electrode 641 make ohmic contact with the barrier layer 621 to ensure efficient carrier injection. The gate electrode 637 is separated from the barrier layer 621 by a gate barrier layer 633, which can be a semiconductor or dielectric material. In some embodiments, the gate barrier layer 633 is a semiconductor material which allows it to be used in the Schottky diode 605.

The HEMT 601 may include one or more field plates to implement a reduced surface field (RESURF) technique. This technique extends the depletion region, reduces the maximum electric field, and thereby enhances the breakdown voltage and reliability of the HEMT 601. In the illustrated configuration, the HEMT 601 includes a gate field plate (GFP) 635, a first source field plate (SFP) 639, and a second source field plate (SFP) 629. The GFP 635 is integrated with the gate electrode 637 and extends from the gate electrode 637 towards the drain electrode 641 and aids in electric field modulation. The first SFP 639 and the second SFP 629 are electrically connected to the source electrode 627 for efficient charge redistribution. The first SFP 639 has a drain-facing edge positioned closer to the drain electrode 641 than the drain-facing edge of the GFP 635. The second SFP 629 is stacked above the first SFP 639 and has a drain-facing edge that is positioned closer to the drain electrode 641 than the corresponding edge of the first SFP 639.

The HEMT 601 may be configured to serve as the high-voltage device 145, the forward-triggering FET 131, or the reverse-triggering FET 119 (see FIG. 1). The illustrated configuration is adapted for the high-voltage device 145, featuring field plates and a drain-to-gate distance 643 that is greater than the source-to-gate distance 631. To implement the forward-triggering FET 131 or the reverse-triggering FET 119, one or more field plates may be made smaller or omitted, and the drain-to-gate distance 643 may be reduced.

Additionally, the high-voltage device 145 has a much greater channel width compared to the forward-triggering FET 131 and the reverse-triggering FET 119. For example, the channel width may be in the range from about 100 mm to about 300 mm. On the other hand, the high-voltage device 145 may occupy a chip area limited to about 10 mm by 10 mm. To achieve the channel width within a limited chip area, the high-voltage device 145 utilizes an undulating or meandering (extending in multiple and varying directions) channel design, allowing the channel to extend back and forth across the area. Alternatively, multiple parallel structures may be connected to achieve the desired channel width. In contrast, the forward-triggering FET 131 and the reverse-triggering FET 119 have channel widths that are typically smaller than the high-voltage device 145 by a factor of 100 or more and can be implemented with single linear channels.

The diode-connected transistor 603 is similar to the HEMT 601, except for a metal interconnect 649 that electrically connects the source electrode 627 to the gate electrode 637. In the illustrated example, the diode-connected transistor 603 lacks the GFP 635, the first SFP 639, and the second SFP 629. Additionally, the drain-to-gate distance 643 is equal to the source-to-gate distance 631. These modifications simplify the design and manufacturing process, reducing complexity and cost. The rectifiers 117 (see FIG. 1) can be implemented using diode-connected transistors 603.

The Schottky diode 605 includes a first terminal 645, which is structurally similar to the source electrodes 627, and a second terminal 647, which is structurally similar to the gate electrodes 637. A Schottky junction is formed at the interface between the second terminal 647 and the gate barrier layer 633. The rectifiers 117 (see FIG. 1) can be implemented using the Schottky diode 605. Alternatively, the rectifiers 117 may be implemented using Zener diodes, PN junction diodes, or the like. However, these alternative structures may not integrate as seamlessly with the high-voltage device 145 (see FIG. 1) as the diode-connected transistors 603 or Schottky diodes 605. A rectifier can be any circuit component that allows current to flow predominantly in one direction, and would be functional to convert alternating current (AC) to direct current (DC) by blocking or significantly reducing current flow in the reverse direction. As noted above, examples include diodes and diode-connected transistors.

The resistor 607 includes a first terminal 651 and a second terminal 653, which are structurally similar to the source electrodes 627 and the drain electrodes 641. The resistance of the resistor 607 can be controlled by varying the width of the active semiconductor region between the first terminal 651 and the second terminal 653.

FIG. 7 illustrates a cross-sectional view of an integrated circuit device 700, showing a voltage-divider network 113A as an example implementation of the first voltage-divider network 113 (see FIG. 3). The voltage-divider network 113A comprises diode-connected transistors 603A-603D connected in series between the input signal wire 109 and the reference signal wire 141. The diode-connected transistors 603A-603D share source/drain regions 701 within the semiconductor layers 628. This use of shared source/drain regions 701 results in a more compact structure, while also reducing resistance and capacitance. The node 137, which couples to the gate 135 of the forward-triggering FET 131 (see FIG. 3), is positioned between the diode-connected transistors 603C and 603D.

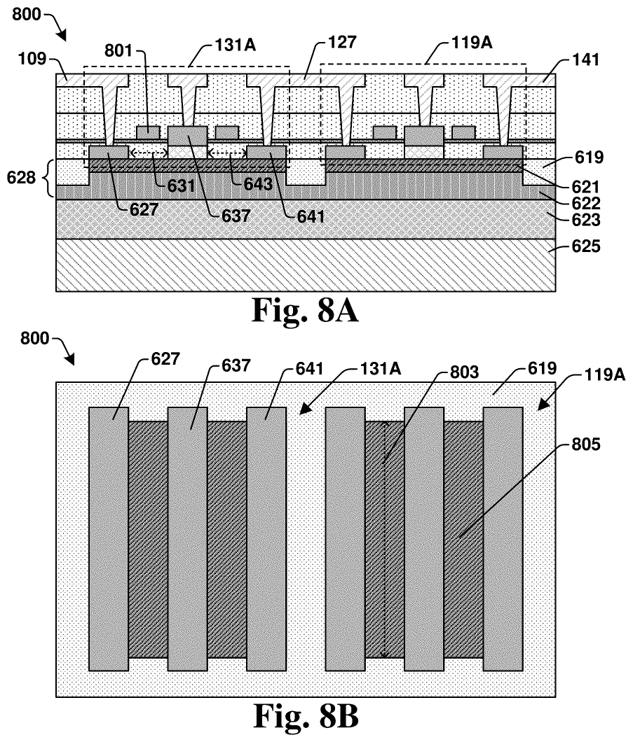

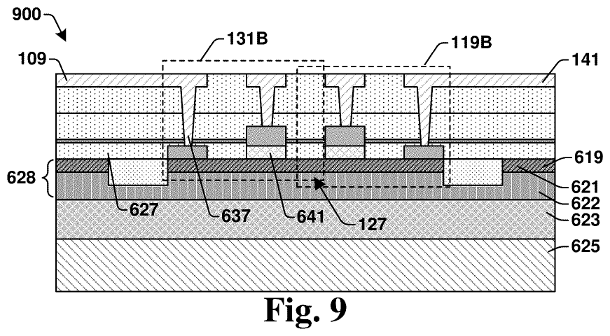

FIGS. 8A and 8B illustrate a cross-sectional view and a plan view, respectively, of an integrated circuit device 800 featuring a forward-triggering FET 131A and a reverse-triggering FET 119A as example implementations of the forward-triggering FET 131 and the reverse-triggering FET 119 (see FIG. 1). These FETs are connected in series between the input signal wire 109 and the reference signal wire 141, forming the main discharge path of a transient voltage protection circuit. In some embodiments, the forward-triggering FET 131A and the reverse-triggering FET 119A are symmetrical about the floating node 127, enabling equivalent responses to positive and negative voltage spikes. Furthermore, the forward-triggering FET 131A and the reverse-triggering FET 119A are designed with drain-to-gate distances 643 equal to their source-to-gate distances 631. This symmetry simplifies the design and manufacturing process, reducing complexity and overall cost.

In some embodiments, the forward-triggering FET 131A and the reverse-triggering FET 119A do not use field plates. In some embodiments, the forward-triggering FET 131A and the reverse-triggering FET 119A have field plates which are symmetrical about respective gate electrodes 637. The field plates 801 provide an example. The field plates 801 are provided in pairs, one between the drain electrode 641 and the gate electrode 637, the other between the gate electrode 637 and the source electrode 627.

Referring to the plan view in FIG. 8B, the isolation structure 619 surrounds and defines active areas 805, which provide the channels for the forward-triggering FET 131A and the reverse-triggering FET 119A. The channel widths are determined by the widths 803 of the active areas 805.

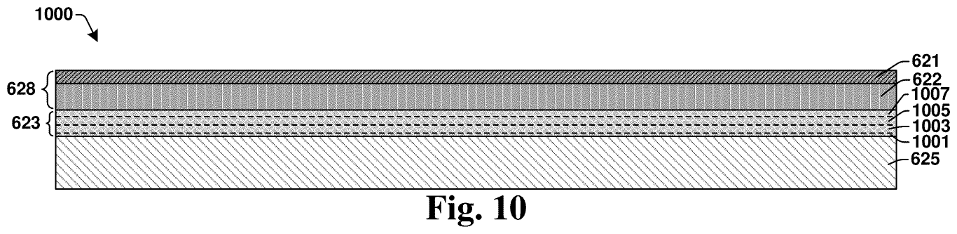

FIG. 9 illustrates a cross-sectional view of an integrated circuit device 900, featuring a forward-triggering FET 131B and a reverse-triggering FET 119B as another possible implementation of the forward-triggering FET 131 and the reverse-triggering FET 119 (see FIG. 1). The forward-triggering FET 131B and the reverse-triggering FET 119B share a common source/drain region within the semiconductor layers 628. This shared source/drain region also serves as the floating node 127. The use of a shared source/drain region results in a more compact structure and reduces both resistance and parasitic capacitance, enhancing device performance and efficiency.

FIGS. 10-23 provide a series of cross-sectional views 1000-2300 that illustrate an integrated circuit device according to the present disclosure at various stages of manufacture according to a process of the present disclosure. Although FIGS. 10-23 are described in relation to a series of acts, it will be appreciated that the order of the acts may in some cases be altered and that this series of acts are applicable to structures other than the ones illustrated. In some embodiments, some of these acts may be omitted in whole or in part. Furthermore, while FIGS. 10-23 are described in relation to a series of acts, it will be appreciated that the structures shown in FIGS. 10-23 are not limited to a method of manufacture but rather may stand alone as structures separate from the method.

As illustrated by the cross-sectional view 1000 of FIG. 10, the buffer layer stack 623, the channel layer 622, and the barrier layer 621 are deposited over the substrate 625. These layers can be deposited by metal organic chemical vapor deposition (MOCVD) and/or by some other suitable deposition process. The substrate 625 can be or comprise silicon, sapphire, some other suitable crystalline material, or any combination of the foregoing. In some embodiments, the substrate 625 is a bulk semiconductor substrate and/or is a semiconductor wafer. In some embodiments, the substrate 625 is or comprises silicon.

The buffer layer stack 623 comprises a nucleation layer 1001, a graded buffer layer 1003, a super lattice buffer layer 1005, and a high resistivity buffer layer 1007 stacked between the substrate 625 and the channel layer 622. Alternatively, one or more of these layers is omitted. The nucleation layer 1001 can be or comprise, for example, aluminum nitride (AlN). The graded buffer layer 1003 can be or comprise, for example, aluminum gallium nitride (AlₓGa₁₋ₓN) with the proportionality factor x varying monotonically through its thickness. The super lattice buffer layer 1005 may be or comprises, for example, aluminum nitride (AlN) and gallium nitride (GaN) in alternating layers. The high resistivity buffer layer 1007 can be or comprise, for example, carbon or iron doped gallium nitride (e.g., GaN:C or GaN:Fe).

The channel layer 622 can be or comprise, for example, gallium nitride (GaN). The barrier layer 621 can be or comprise, for example, aluminum gallium nitride (AlGaN). Alternatively, the semiconductor layers 628 may be some other pair of group III-V semiconductor materials that provide a heterojunction that supports a 2 DEG, a pair of group II-VI semiconductor materials that support a 2 DEG, or the like. These alternatives include, without limitation, examples in which the channel layer 622 is gallium arsenide (GaAs) or indium phosphide (InP). In some embodiments, the semiconductor layers 628 have a thickness of about 10 μm or less. In some embodiments, the semiconductor layers 628 have a thickness of about 5 μm or less. It is difficult to form thicker epitaxial layers of suitable materials over silicon without introducing defects.

A protection circuit according to the present disclosure is not limited to substrates that support a 2 DEG, but may be implemented on any type of substrate. In some other embodiments, a substrate of silicon (Si), gallium nitride (GaN), silicon carbide (SiC), gallium arsenide (GaAs), or the like is used in place of the substrate structure illustrated by the cross-sectional view 1000 of FIG. 10.

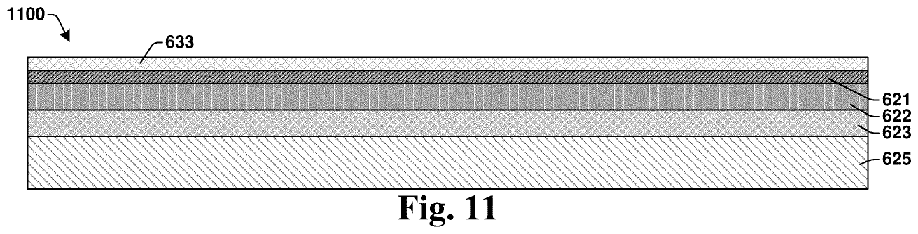

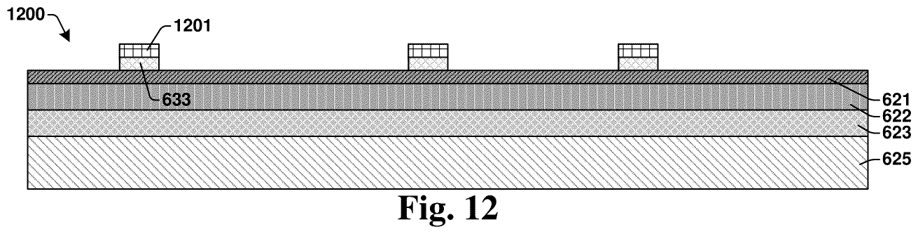

As illustrated by the cross-sectional view 1100 of FIG. 11, the gate barrier layer 633 is formed over the barrier layer 621. In some embodiments, the gate barrier layer 633 is or comprises p-doped gallium nitride (p-GaN) or some other suitable semiconductor. In other embodiments, the gate barrier layer 633 is a dielectric. The dielectric can be silicon dioxide (SiO₂), a high-k dielectric or the like. The gate barrier layer 633 may be deposited by MOCVD, another type of CVD process, physical vapor deposition (PVD), atomic layer deposition (ALD), the like, or any other suitable process.

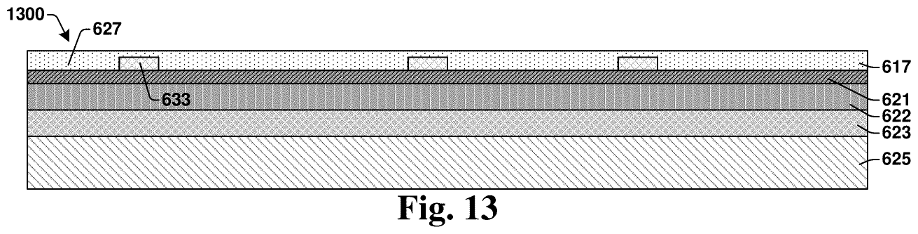

As illustrated by the cross-sectional view 1200 of FIG. 12, a mask 1201 is formed and used to pattern the gate barrier layer 633. The mask 1201, as well as other masks used in the processes described herein, may comprise a photoresist, a hard mask, or similar materials. The mask 1201 and other masks employed in these processes may be patterned using photolithography, ion beam lithography, or another suitable patterning technique. The etching process may be a dry etch, such as a plasma etch, or another appropriate etching method. After etching, the mask 1201 may be stripped.

As illustrated by the cross-sectional view 1300 of FIG. 13, an interlayer dielectric (ILD) layer 617 is deposited covering the patterned gate barrier layer 633. The ILD layer 617 may be silicon dioxide (SiO₂), a low-k dielectric, the like, or some other suitable dielectric. The deposition process may be CVD, PVD, ALD, the like, or some other suitable deposition process. In some embodiments, the ILD layer 617 is planarized after deposition. The planarization process may be, for example, chemical mechanical polish (CMP) or the like.

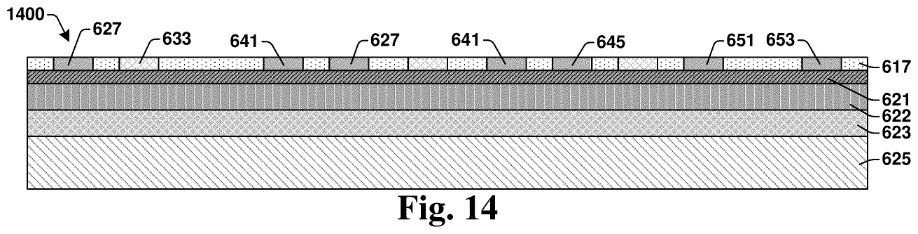

As shown in the cross-sectional view 1400 of FIG. 14, the source electrode 627, the drain electrode 641, and similar electrodes are formed within the ILD layer 617. These electrodes can be fabricated using a damascene process, which typically involves: 1) patterning the ILD layer 617 to create openings; 2) depositing a conductive layer over the ILD layer 617 to fill the openings; and 3) performing a planarization process, such as chemical-mechanical polishing (CMP), to remove the excess conductive material outside the openings. Alternatively, another suitable fabrication technique may be employed. The conductive material for the electrodes may include, for example, aluminum, titanium, nickel, gold, copper, tungsten, tantalum, or the like. In some embodiments, the conductive material is specifically chosen to have a work function lower than that of the barrier layer 621, ensuring that the electrodes form ohmic contacts with the barrier layer 621.

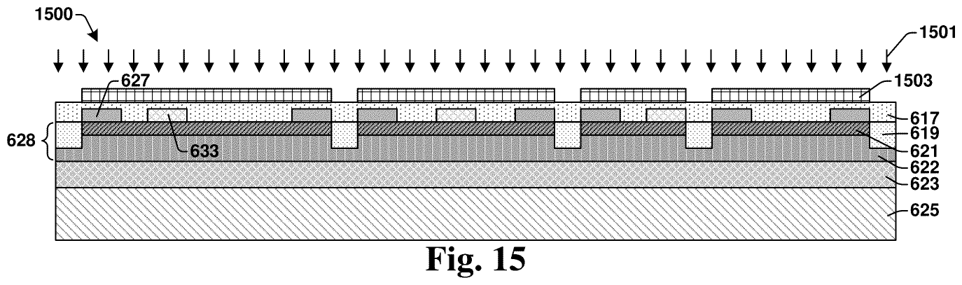

As illustrated by the cross-sectional view 1500 of FIG. 15, a mask 1503 may be formed and oxygen 1501 implanted into the semiconductor layers 628 through openings in the mask to form the isolation structures 619. In some embodiments, the implantation is ion implantation, and the oxygen 1501 is in the form of oxygen ions. Other suitable processes for performing the implantation may also be used. After the implantation, the mask 1503 is stripped. The isolation structures 619 may alternatively be a different type of isolations structure formed by a different type of process. For example, the isolation structures 619 may be shallow trench isolation structures formed prior to the gate barrier layer 633 by etching, filling, and planarizing.

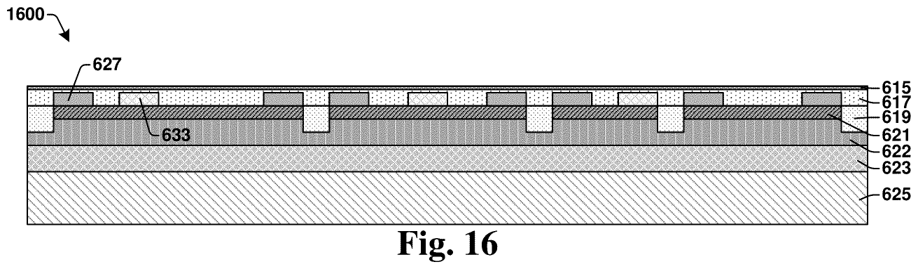

As illustrated by the cross-sectional view 1600 of FIG. 16, a first etch stop layer 615 is deposited covering the ILD layer 617. The first etch stop layer 615 is a different material type than the ILD layer 617. For example, the first etch stop layer 615 may be or comprise silicon nitride and/or silicon carbide, whereas the ILD layer 617 may, for example, be or compromise an oxide. More generally, the first etch stop layer 615 may be any suitable dielectric material.

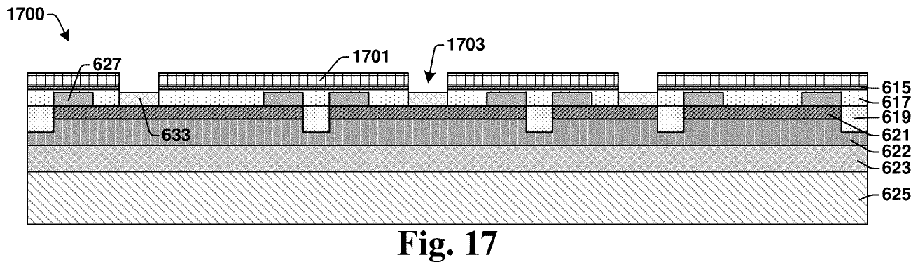

As illustrated by the cross-sectional view 1700 of FIG. 17, a mask 1701 is formed and used to pattern holes 1703 through the first etch stop layer 615 and the ILD layer 617 over the islands of the gate barrier layer 633. The holes 1703 may be narrower than islands of the gate barrier layer 633 to ensure that the holes 1703 are formed exclusively over the gate barrier layer 633. The etch process may be a plasma etch, the like, or any other suitable etch process. After etching, the mask 1701 may be stripped.

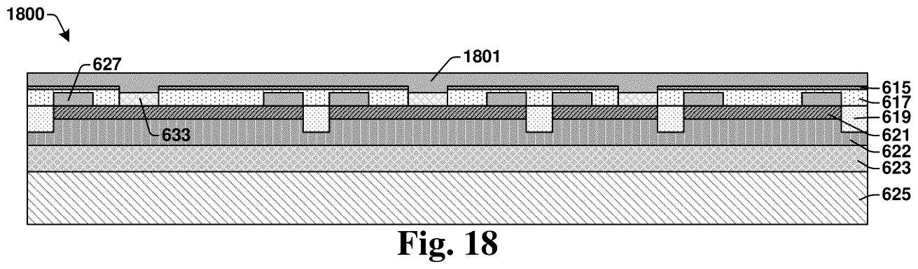

As illustrated by the cross-sectional view 1800 of FIG. 18, a conductive layer 1801 is deposited to cover the first etch stop layer 615 and fill the holes 1703. The conductive layer 1801 may be, for example, nickel, gold, platinum, iridium, titanium nitride, aluminum, copper, palladium, the like, some other suitable metal(s) and/or metallic material(s), or any combination of the foregoing. The deposition process may be electroplating, electroless plating, CVD, PVD, ALD, the like, or any other suitable process.

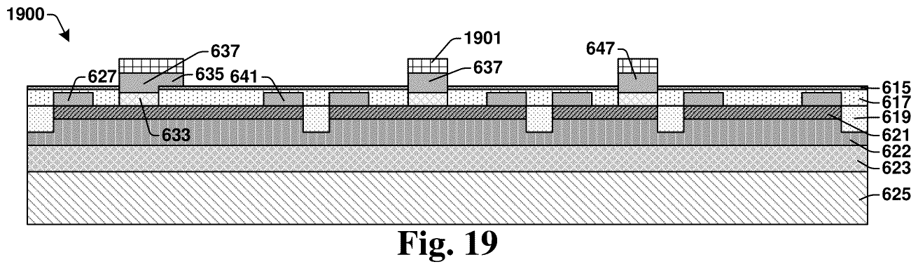

As illustrated by the cross-sectional view 1900 of FIG. 19, a mask 1901 is formed and used to pattern the conductive layer 1801 to form the gate electrodes 637, the second terminal 647, and the GFP 635. The etch process may be a dry etch such as a plasma etch, or the like. After etching, the mask 1901 may be stripped.

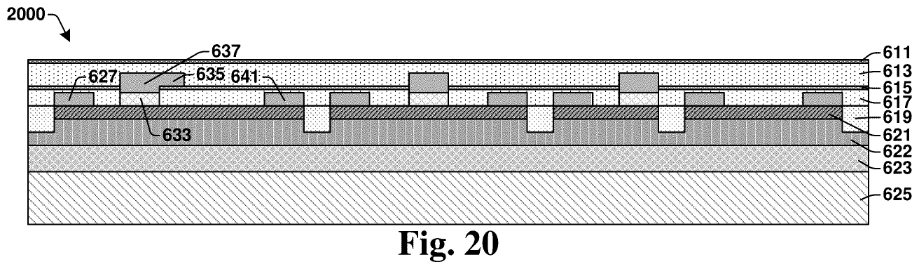

As illustrated by the cross-sectional view 2000 of FIG. 20, a first inter-metal dielectric (IMD) layer 613 and a second etch stop layer 611 may be deposited over the structure illustrated by the cross-sectional view 1900 of FIG. 19. These layers may be deposited by CVD, PVD, ALD, the like, or any other suitable processes. In some embodiments, the first IMD layer 613 is planarized before depositing the second etch stop layer 611. The planarization process may be, for example, CMP or the like. The second etch stop layer 611 is a different material type than the first IMD layer 613. For example, the second etch stop layer 611 may be or comprise, for example, silicon nitride and/or silicon carbide, whereas the first IMD layer 613 may be or comprise, for example, silicon dioxide (SiO₂) or a low-k dielectric. Alternatively, another suitable combination of dielectric materials may be used.

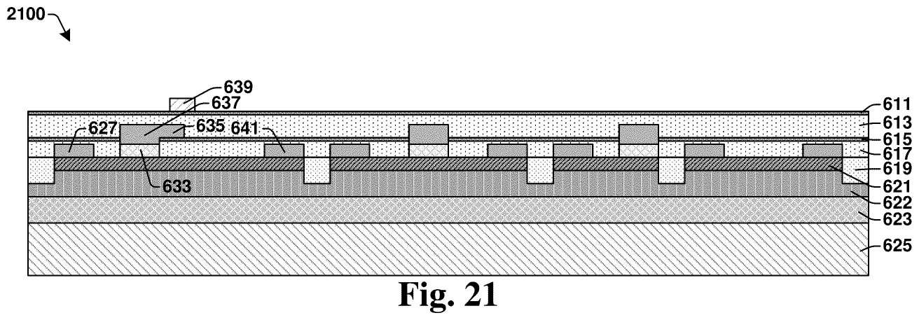

As illustrated by the cross-sectional view 2100 of FIG. 21, the first SFP 639 is formed over the second etch stop layer 611. A process for forming the first SFP 639 may include depositing a conductive layer overlying the second etch stop layer 611 and patterning the conductive layer to form the first SFP 639. The conductive layer may be titanium nitride (TiN), another metallic material, a metal, or the like. The deposition process may be electroplating, electroless plating, CVD, PVD, ALD, the like, or any other suitable process. The patterning process may be, for example, a dry etch such as a plasma etch or the like.

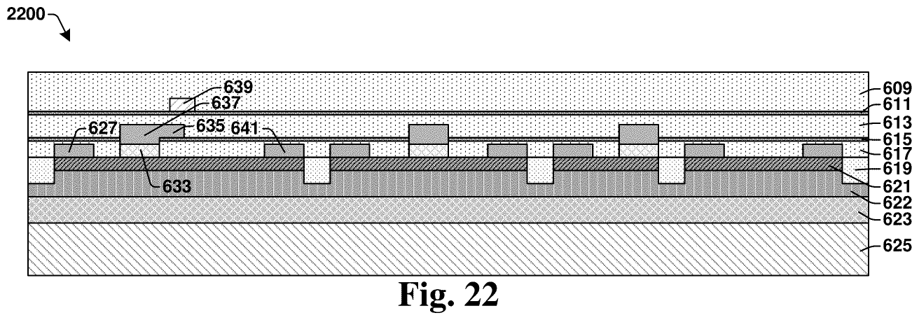

As illustrated by the cross-sectional view 2200 of FIG. 22, a second IMD layer 609 is deposited overlying the second etch stop layer 611 and the first SFP 639. The deposition process may be electroplating, electroless plating, CVD, PVD, ALD, the like, or any other suitable process. In some embodiments, the second IMD layer 609 is planarized. The planarization may be, for example, CMP or the like.

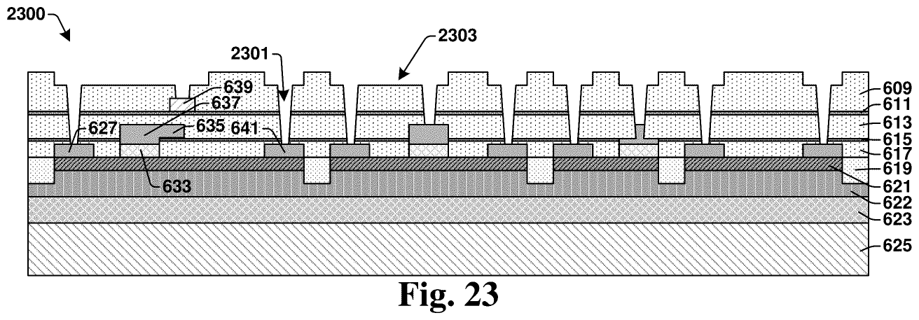

As illustrated by the cross-sectional view 2300 of FIG. 23 and FIG. 1, a metal interconnect structure 626 is formed to provide various metal interconnects between electrodes and between electrodes and field plates. The second SFP 629 may be formed with and be a part of the metal interconnect structure 626. The metal interconnect structure 626 comprises wires and vias in the ILD layer 617, the first IMD layer 613, and the second IMD layer 609. Additional metal interconnect layers may also be formed to provide wires and make necessary connections. These layers may be formed by damascene or dual damascene processes.

As illustrated by the cross-sectional view 2300 of FIG. 23, a process of forming the metal interconnect structure 626 may begin with etching trenches 2303 and holes 2301. The trenches 2303 and the holes 2301 may be filled with metal to provide a structure as shown in FIG. 1. The metal may be aluminum, copper, a combination thereof, the like, or some other suitable conductive material. The metal may be deposited by electroplating, electroless plating, CVD, PVD, ALD, the like, or any other suitable process. Excess metal may be removed by a planarization process such as CMP or the like.

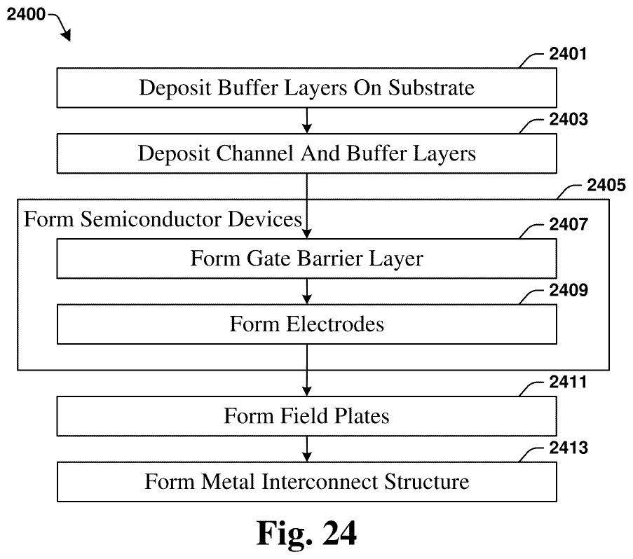

FIG. 24 provides a flow diagram for a method 2400 of forming an IC device according to some embodiments. While the method 2400 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2400 can begin with act 2401, depositing buffer layers over a semiconductor body. These buffer layer may accommodate lattice and thermal expansion coefficient mismatches between the semiconductor body and subsequently formed epitaxial layer. They may also provide electrical insulation. The cross-sectional view 1000 of FIG. 10 provides an example.

Act 2403 is depositing channel and barrier layers over the buffer layers. These layers form a heterojunction that supports a 2 DEG. The cross-sectional view 1000 of FIG. 10 provides an example.

Act 2405 is a series of acts that form IC devices that include portions of the channel and barrier layers. In some embodiments, these acts form a voltage protection circuit using the same processing steps that form a high-voltage device that is protected by that circuit. The acts include act 2407 forming a gate barrier layer, and act 2409, forming electrodes. Some of these electrode may form ohmic contacts with the barrier layer. Others of these electrodes may be disposed over the gate barrier layer to form gate electrodes and the like. The cross-sectional views 1100-1900 of FIGS. 11-19 provide an example.

Act 2411 is forming field plates for transistors. The cross-sectional views 2000-2100 of FIGS. 20-21 provide an example. Additional field plates may be formed in conjunction with act 2409, forming electrodes, and/or act 2413, forming a metal interconnect structure.

Act 2413 is forming a metal interconnect structure which provides an input signal wire and a reference signal wire, and interconnects the semiconductor devices. The cross-sectional views 2200-2300 of FIGS. 22-23 provide an example.

Some aspects of the present disclosure relate to an IC device with a transient voltage protection circuit connected between a first terminal and a second terminal. The transient voltage protection circuit includes a forward-triggering FET and a reverse-triggering FET connected in series between the first terminal and the second terminal, a first voltage-divider network connected between the first terminal and the second terminal, and a second voltage-divider network connected between the first terminal and the second terminal. The first voltage-divider network includes a series arrangement of first circuit elements and is configured to control a gate voltage of the forward-triggering FET such that the forward-triggering FET closes when a voltage of the first terminal exceeds a voltage of the second terminal by a first predefined threshold. At east one of the first circuit elements includes a first rectifier configured to protect a gate of the forward-triggering FET against positive voltage spikes originating at the second terminal. The second voltage-divider network includes a series arrangement of second circuit elements configured to control a gate voltage of the reverse-triggering FET such that the reverse-triggering FET closes when a voltage of the second terminal exceeds a voltage of the first terminal by a second predefined threshold. At least one of the second circuit elements includes a second rectifier configured to protect a gate of the reverse-triggering FET against positive voltage spikes originating at the first terminal.

In some embodiments, the IC device includes an HEMT having a channel formed by a heterojunction between a type III-V semiconductor and a ternary III-V compound semiconductor and a gate, wherein the first terminal is coupled to the gate of the HEMT and the transient voltage protection circuit is configured to protect the gate of the HEMT. In some embodiments, the forward-triggering FET has a channel formed by the heterojunction between the type III-V semiconductor and the ternary III-V compound semiconductor. In some embodiments, first voltage-divider network comprises a rectifier having a body in either the type III-V semiconductor or the ternary III-V compound semiconductor. In some embodiments, first voltage-divider network comprises a diode-connected HEMT having a channel formed by the heterojunction between the type III-V semiconductor and the ternary III-V compound semiconductor. In some embodiments, the first voltage-divider network has a forward threshold voltage drop less than a gate breakdown voltage for the HEMT.

In some embodiments, the first voltage-divider network has a forward threshold voltage drop less than the first predefined threshold. In some embodiments, the first voltage-divider network and the second voltage-divider network have equal numbers of rectifiers. In some embodiments, the first voltage-divider network and the second voltage-divider network have distinct forward threshold voltage drops. In some embodiments, the first rectifier electrically couples the gate of the forward-triggering FET to the second terminal.

In some embodiments, the first voltage-divider network has a greater number of rectifiers between the first terminal and the gate of the forward-triggering FET than between the gate of the forward-triggering FET and the second terminal. In some embodiments, the first voltage-divider network has three or more times as many rectifiers between the first terminal and the gate of the forward-triggering FET than between the gate of the forward-triggering FET and the second terminal. In some embodiments, the first voltage-divider network, when forward biased to conduct between the first terminal and the second terminal, has a greater resistance between the first terminal and the gate of the forward-triggering FET than between the gate of the forward-triggering FET and the second terminal. In some embodiments, the forward-triggering FET and the reverse-triggering FET are symmetrical about a floating node between the forward-triggering FET and the reverse-triggering FET. In some embodiments, the forward-triggering FET has equal gate-to-source and gate-to-drain distances. In some embodiments, the first circuit elements in the first voltage-divider network have shared source/drain regions.

Some aspects of the present disclosure relate to a method of manufacturing an IC device, the method including forming a first group of rectifiers connected in series between an input signal wire and a reference signal wire and oriented to preferentially allow current from the input signal wire to the reference signal wire; forming a second group of rectifiers connected in series between the input signal wire and the reference signal wire and oriented to preferentially allow current from the reference signal wire to the input signal wire, forming a forward-triggering field effect transistor (FET) having a gate electrically coupled to a node between two rectifiers in the first group of rectifiers, forming a reverse-triggering FET having a gate electrically coupled to a node between two rectifiers in the second group of rectifiers, and connecting the forward-triggering FET and the reverse-triggering FET in series between the input signal wire to the reference signal wire. In some embodiments, the method further includes forming a high electron mobility transistor (HEMT) and connecting a gate of the HEMT to the input signal wire.

Some aspects of the present disclosure relate to a method of manufacturing an IC device, the method including forming a channel layer comprising a second semiconductor material over a substrate comprising a first semiconductor material, forming a barrier layer comprising a third semiconductor material over the channel layer, forming a HEMT and components of a gate protection circuit for the HEMT, wherein the components of the gate protection circuit include a forward-triggering field effect transistor (FET), a reverse-triggering FET, a first group of rectifiers, and a second group of rectifiers, wherein the HEMT and each of the components of the gate protection circuit comprises a portion of the barrier layer and/or the channel layer, and forming a metal interconnect structure over the HEMT and the components of a gate protection circuit, wherein the metal interconnect structure provides a reference signal wire and an input signal wire. The input signal wire is electrically connected to a gate of the HEMT, the first group of rectifiers is electrically connected in series between the input signal wire and the reference signal wire with their forward directions toward the reference signal wire, the second group of rectifiers is electrically connected in series between the reference signal wire and the input signal wire with their forward directions toward the input signal wire, a node between two of the rectifiers in the first group is electrically connected to a gate of the forward-triggering FET, a node between two of the rectifiers in the second group is electrically connected to a gate of the reverse-triggering FET, and the forward-triggering FET and the reverse-triggering FET are electrically connected in series between the input signal wire and the reference signal wire. In some embodiments, the rectifiers in the first group are diode-connected HEMTs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a transient voltage protection circuit connected between a first terminal and a second terminal, the transient voltage protection circuit comprising:
a forward-triggering field effect transistor (FET) and a reverse-triggering FET connected in series between the first terminal and the second terminal;
a first voltage-divider network comprising a series arrangement of first circuit elements, wherein the first voltage-divider network is connected between the first terminal and the second terminal, the first voltage-divider network is configured to control a gate voltage of the forward-triggering FET such that the forward-triggering FET closes when a voltage of the first terminal exceeds a voltage of the second terminal by a first predefined threshold, and wherein at least one of the first circuit elements includes a first rectifier configured to protect a gate of the forward-triggering FET against positive voltage spikes originating at the second terminal; and
a second voltage-divider network comprising a series arrangement of second circuit elements, wherein the second voltage-divider network is connected between the first terminal and the second terminal, the second voltage-divider network is configured to control a gate voltage of the reverse-triggering FET such that the reverse-triggering FET closes when a voltage of the second terminal exceeds a voltage of the first terminal by a second predefined threshold, and wherein at least one of the second circuit elements includes a second rectifier configured to protect a gate of the reverse-triggering FET against positive voltage spikes originating at the first terminal.

2. The IC device of claim 1, further comprising a high electron mobility field effect transistor (HEMT) having a channel formed by a heterojunction between a type III-V semiconductor and a ternary III-V compound semiconductor and a gate, wherein the first terminal is coupled to the gate of the HEMT and the transient voltage protection circuit is configured to protect the gate of the HEMT.

3. The IC device of claim 2, wherein the forward-triggering FET has a channel formed by the heterojunction between the type III-V semiconductor and the ternary III-V compound semiconductor.

4. The IC device of claim 3, wherein first voltage-divider network comprises a rectifier having a body in either the type III-V semiconductor or the ternary III-V compound semiconductor.

5. The IC device of claim 3, wherein first voltage-divider network comprises a diode-connected HEMT having a channel formed by the heterojunction between the type III-V semiconductor and the ternary III-V compound semiconductor.

6. The IC device of claim 2, wherein the first voltage-divider network has a forward threshold voltage drop less than a gate breakdown voltage for the HEMT.

7. The IC device of claim 1, wherein the first voltage-divider network has a forward threshold voltage drop less than the first predefined threshold.

8. The IC device of claim 1, wherein the first voltage-divider network and the second voltage-divider network have equal numbers of rectifiers.

9. The IC device of claim 1, wherein the first voltage-divider network and the second voltage-divider network have distinct forward threshold voltage drops.

10. The IC device of claim 1, wherein the first rectifier electrically couples the gate of the forward-triggering FET to the second terminal.

11. The IC device of claim 1, wherein the first voltage-divider network has a greater number of rectifiers between the first terminal and the gate of the forward-triggering FET than between the gate of the forward-triggering FET and the second terminal.

12. The IC device of claim 11, wherein the first voltage-divider network has three or more times as many rectifiers between the first terminal and the gate of the forward-triggering FET than between the gate of the forward-triggering FET and the second terminal.

13. The IC device of claim 1, wherein the first voltage-divider network, when forward biased to conduct between the first terminal and the second terminal, has a greater resistance between the first terminal and the gate of the forward-triggering FET than between the gate of the forward-triggering FET and the second terminal.

14. The IC device of claim 1, wherein the forward-triggering FET and the reverse-triggering FET are symmetrical about a floating node between the forward-triggering FET and the reverse-triggering FET.

15. The IC device of claim 1, wherein the forward-triggering FET has equal gate-to-source and gate-to-drain distances.

16. The IC device of claim 1, wherein the first circuit elements in the first voltage-divider network have shared source/drain regions.

17. An integrated circuit (IC) device, comprising:
a first group of rectifiers connected in series between an input signal wire and a reference signal wire, wherein the first group of rectifiers are oriented to preferentially allow current from the input signal wire to the reference signal wire;
a second group of rectifiers connected in series between the input signal wire and the reference signal wire, wherein the second group of rectifiers are oriented to preferentially allow current from the reference signal wire to the input signal wire;
a forward-triggering field effect transistor (FET) having a gate electrically coupled to a node between two rectifiers in the first group of rectifiers; and
a reverse-triggering FET having a gate electrically coupled to a node between two rectifiers in the second group of rectifiers, and wherein the forward-triggering FET and the reverse-triggering FET in series between the input signal wire to the reference signal wire.

18. The IC device of claim 17, further comprising a high electron mobility transistor (HEMT), wherein a gate of the HEMT is connected to the input signal wire.

19. An integrated circuit (IC) device, comprising:
a channel layer comprising a second semiconductor material over a substrate comprising a first semiconductor material;
a barrier layer comprising a third semiconductor material over the channel layer;
a high electron mobility transistor (HEMT), wherein the HEMT comprises a first portion of the barrier layer and/or the channel layer;
a gate protection circuit for the HEMT, wherein components of the gate protection circuit including a forward-triggering field effect transistor (FET), a reverse-triggering FET, a first group of rectifiers, and a second group of rectifiers comprise second portions of the barrier layer and/or the channel layer; and
a metal interconnect structure over the HEMT and the components of a gate protection circuit;
wherein the metal interconnect structure provides a reference signal wire and an input signal wire;
the input signal wire is electrically connected to a gate of the HEMT;
the first group of rectifiers is electrically connected in series between the input signal wire and the reference signal wire with their forward directions toward the reference signal wire;
the second group of rectifiers is electrically connected in series between the reference signal wire and the input signal wire with their forward directions toward the input signal wire;
a node between two of the rectifiers in the first group is electrically connected to a gate of the forward-triggering FET;
a node between two of the rectifiers in the second group is electrically connected to a gate of the reverse-triggering FET; and
the forward-triggering FET and the reverse-triggering FET are electrically connected in series between the input signal wire and the reference signal wire.

20. The IC device of claim 19, wherein the rectifiers in the first group comprise diode-connected HEMTs.
